(19) United States
(12) Patent Application Publication
(10) Pub. No.: US 2025/0212466 A1
(43) Pub. Date: Jun. 26, 2025

(54) SEMICONDUCTOR DEVICE AND METHOD FOR FORMING THE SAME

(71) Applicant: Winbond Electronics Corp., Taichung City (TW)

(72) Inventors: Yung-Han CHIU, Taichung City (TW); Shu-Ming LI, Kaohsiung City (TW)

(21) Appl. No.: 18/935,081

(22) Filed: Nov. 1, 2024

(30) Foreign Application Priority Data
Dec. 21, 2023 (TW) 112150043

(51) Int. Cl. H01L 29/788; H01L 29/423; H01L 29/66

(52) U.S. Cl. CPC H10D 30/68; H10D 30/0411; H10D 30/6891

(57) ABSTRACT

A semiconductor device is provided. The semiconductor device includes a substrate, isolation structures, semiconductor structures, a dielectric structure, and a control gate. The semiconductor structures are disposed between the isolation structures. Each of the semiconductor structures includes a tunneling dielectric layer disposed on the substrate, a floating gate disposed on the tunneling dielectric layer. The floating gate includes an upper portion and a lower portion. The width of the lower portion is greater than or equal to the width of the upper portion. The upper portion includes a flat part and a protruding part protruding from the flat part. The width of the flat part is greater than the width of the protruding part. The dielectric structure is disposed on the semiconductor structures. The control gate is disposed on the dielectric structure.

### CROSS REFERENCE TO RELATED APPLICATIONS

This application claims priority of Taiwan Patent Application No. 112150043, filed on Dec. 21, 2023, the entirety of which is incorporated by reference herein.

### BACKGROUND OF THE INVENTION

### Field of the Invention

The present invention relates to a semiconductor device, and, in particular, to a semiconductor device with an improved gate coupling ratio and a method for forming the same.

### Description of the Related Art

As the size of electronic products and semiconductor devices continues to shrink, many challenges arise. For example, in the flash memory manufacturing process, the number of electrons that can be controlled by the control gate decreases as the device is scaled down. Moreover, deepening the control gate trench between floating gates increases the risk of a short circuit between the floating gates. Therefore, the industry still needs to improve the manufacturing method of flash memory to overcome the problems caused by scaling down.

### BRIEF SUMMARY OF THE INVENTION

An embodiment of the present invention provides a semiconductor device. The semiconductor device includes a substrate, a plurality of isolation structures, a plurality of semiconductor structures, a dielectric structure, and a control gate. The isolation structures are disposed in the substrate. The semiconductor structures are disposed between the isolation structures. Each semiconductor structure includes: a tunneling dielectric layer disposed on the substrate, and a floating gate disposed on the tunneling dielectric layer. The floating gate includes an upper portion and a lower portion. The width of the lower portion is greater than or equal to the width of the upper portion. The upper portion includes a flat part and a protruding part protruding from the flat part. The width of the flat part is greater than the width of the protruding part. A dielectric structure is further disposed on the semiconductor structures. A control gate is further disposed on the dielectric structure.

An embodiment of the present invention provides a method for forming a semiconductor device. The method of forming the semiconductor device includes providing a substrate; forming a plurality of semiconductor structures and a plurality of isolation structures on the substrate. The semiconductor structures and the isolation structures are staggered. The forming the semiconductor structure includes: sequentially forming a floating gate layer and a protective layer on the substrate. The method further includes: recessing the isolation structures to expose a portion of the floating gate layer of each semiconductor structure; patterning the protective layer of each semiconductor structure to reduce the width of the protective layer; and using the patterned protective layer as an etching mask, etching the floating gate layer of each semiconductor structure to form a floating gate layer that is narrow at top and wide at bottom; oxidizing the floating gate layer that is narrow at top and wide at bottom and is not covered by the isolation structure, and the remaining floating gate layer used as a floating gate with three different widths.

### BRIEF DESCRIPTION OF THE DRAWINGS

The present invention can be more fully understood by reading the subsequent detailed description and examples with references made to the accompanying drawings, wherein:

FIGS. 1A-8A and FIGS. 10A-11A are cross-sectional views showing formation of a semiconductor device in an array area according to some embodiments of the present invention.

FIGS. 1B-8B and FIGS. 10B-11B are cross-sectional views showing formation of a semiconductor device in a peripheral area according to some embodiments of the present invention.

FIG. 9 is an enlarged cross-sectional view showing a floating gate according to some embodiments of the present invention.

FIGS. 12A-13A and FIG. 15A are cross-sectional views showing formation of a semiconductor device in an array area according to another embodiments of the present invention.

FIGS. 12B-13B and FIG. 15B are cross-sectional views showing formation of a semiconductor device in a peripheral area according to another embodiments of the present invention.

FIG. 14 is an enlarged cross-sectional view showing a floating gate according to another embodiments of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

Embodiments of the present invention increase the number of electrons controlled by the floating gate by making a portion of the floating gate have dopants. Furthermore, the floating gate with a protruding part is provided to increase the coverage of the control gate to the floating gate. Moreover, making the floating gate have three different widths (i.e., increasing in width as it approaches the tunneling dielectric layer), which may improve gate coupling gate (GCR) of the floating gate and the control gate while preventing short circuits between floating gates.

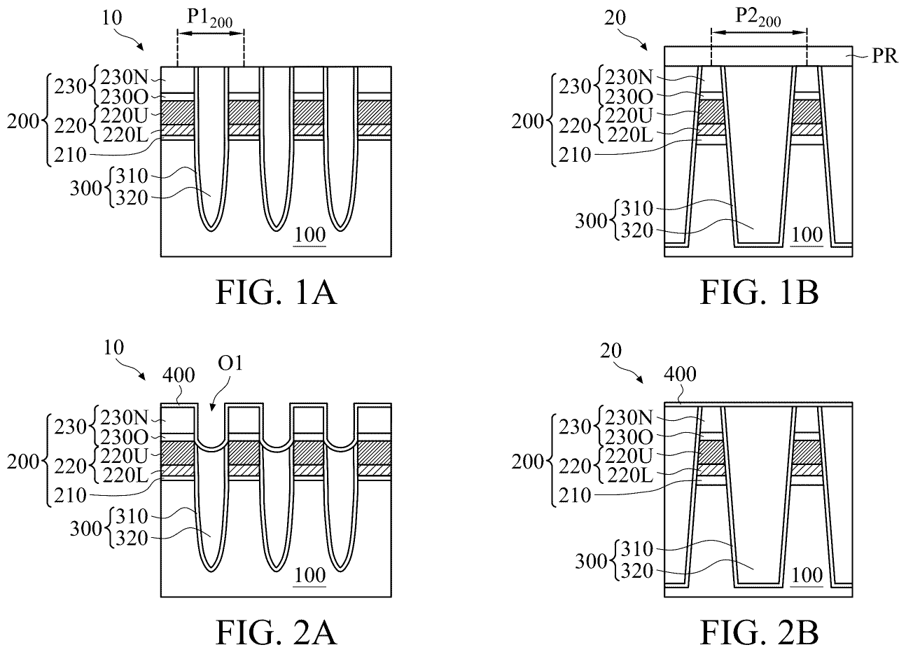

According to some embodiments of the present invention, FIGS. 1A-8A and FIGS. 10A-11A are cross-sectional views showing the formation of semiconductor devices in the array area 10; FIGS. 1B-8B and FIGS. 10B-11B are cross-sectional views showing the formation of semiconductor devices in the peripheral area 20.

First, please referring to FIG. 1A and FIG. 1B, a substrate 100 is provided in the array area 10 and the peripheral area 20. In some embodiments, peripheral area 20 surrounds array area 10 (not shown). Alternatively, in other embodiments, the peripheral area 20 is located on a side of the array area 10 (not shown). It should be noted that the components in the array area 10 in the embodiment of the present invention are generally similar to the components in the peripheral area 20, so the following context focuses on the components in the array area 10.

In some embodiments, the substrate 100 may be an element semiconductor substrate, such as a silicon substrate or a germanium substrate; or a compound semiconductor substrate, such as a silicon carbide substrate, a gallium arsenide substrate, a gallium phosphide substrate, an indium phosphide substrate, an indium arsenide substrate and/or an indium antimonide substrate; or an alloy semiconductor, such as SiGe, GaAsP, AlInAs, AlGaAs, GaInAs, GaInP, GaInAsP, and/or a combination thereof.

Next, continuing referring to FIG. 1A and FIG. 1B, a plurality of semiconductor structures 200 and a plurality of isolation structures 300 are formed on the substrate 100. In some embodiments, the semiconductor structures 200 are staggered with the isolation structures 300. Specifically, forming the semiconductor structures 200 include sequentially forming a tunneling dielectric layer 210, a floating gate layer 220 and a protective layer 230 on the substrate 100.

In some embodiments, the tunneling dielectric layer 210 may include an oxide, a nitride, an oxynitride, or a combination thereof. For example, the tunneling dielectric layer 210 may be silicon oxide, silicon nitride, silicon oxynitride, high-k materials, or a combination thereof. In some embodiments, the formation of the tunneling dielectric layer 210 may include a deposition process or a thermal oxidation process. The aforementioned deposition process may include a chemical vapor deposition (CVD) process, a physical vapor deposition (PVD) process, an atomic layer deposition (ALD) process, or other suitable processes.

It should be noted that the thickness of the tunneling dielectric layer 210 in the peripheral area 20 is thicker than that in the array area 10 in order to withstand a larger voltage.

In some embodiments, the floating gate layer 220 includes an upper portion 220U with dopants and a lower portion 220L without dopants. In some embodiments, the dopants may include N-type or P-type dopants such as nitrogen, arsenic, phosphorus, antimony ions, or boron, aluminum, gallium, indium, boron trifluoride ions (BF³⁺). In the embodiment of the present invention, the dopant is P-type, thereby increasing the number of electrons for subsequent control of the control gate.

In some embodiments, floating gate layer 220 may include conductive materials. For example, the floating gate layer 220 may be doped or undoped polysilicon, amorphous silicon, metal, metal nitride, conductive metal oxide, or combinations thereof. In some embodiments, the formation of may include a deposition process. The aforementioned deposition process may include, for example, a chemical vapor deposition (CVD) process, a physical vapor deposition (PVD) process, an atomic layer deposition (ALD) process, sputtering, resistance heating evaporation, electron beam evaporation, or other suitable processes.

In some embodiments, the protective layer 230 includes an oxide layer 230O and a nitride layer 230N to protect the underlying film layer from being affected by the process.

In some embodiments, the oxide layer 230O includes an oxide, such as tetraethyl orthosilicate (TEOS) oxide. In some embodiments, nitride layer 230N includes nitride, such as silicon nitride (SiN) or silicon oxynitride (SiON). The formation of the oxide layer 230O and the nitride layer 230N may include a deposition process similar to the above, which will not be repeated again here.

The isolation structures 300 are used to define active areas (located on both sides of the isolation structure 300). That is, the isolation structures 300 are disposed between the semiconductor structures 200.

In some embodiments, the isolation structure 300 may be a single layer or multiple layer structure. In the embodiment of the present invention, the isolation structure is a multiple-layer structure, such as an isolation liner 310 and an isolation filling layer 320 on the isolation liner 310. In some embodiments, the isolation structure 300 (including the isolation liner 310 and the isolation filling layer 320) may include dielectric materials, such as silicon oxide, silicon nitride, silicon oxynitride, phosphosilicate glass, borophosphosilicate glass, fluorosilicate glass, undoped silica glass, organosilicate glass, SiOₓCy, spin-on glass, tetraethoxysilane, low dielectric constant dielectric materials, or combinations thereof.

It should be noted that, according to the required design, the pitch P2₂₀₀ of the semiconductor structures 200 in the peripheral area 20 is greater than the pitch P1₂₀₀ of the semiconductor structures 200 in the array area 10, so the shape displayed by the isolation structure 300 will also be slightly different. For example, as shown in FIG. 1A, the isolation structure 300 in the array area 10 has a large aspect ratio, resulting in a water drop-like profile. In comparison, as shown in FIG. 1B, the isolation structure 300 in the peripheral area 20 has a smaller aspect ratio, resulting in a trapezoid-like profile (i.e., a wider bottom).

In some embodiments, the formation of the semiconductor structure 200 and the isolation structure 300 may include: forming a semiconductor structure stack layer on the substrate 100; using a patterned mask and etching the semiconductor structure stack layer by an etching process to generate a plurality of trenches; depositing isolation structure materials in these trenches by a deposition process; removing excess isolation structure materials by a removal process, and the semiconductor structure stack layer is divided into a plurality of semiconductor structures 200 by the trenches, and the remaining isolation structure materials are viewed as the isolation structure 300.

The aforementioned etching process may include an anisotropic etching process, such as a dry etching process. The aforementioned removal process may include a planarization process or the aforementioned etching process. The aforementioned planarization process may include chemical mechanical polishing (CMP).

Continuing referring to FIG. 1A and FIG. 1B, a photoresist PR is formed in the peripheral area 20. Furthermore, the isolation structure 300 in the array area 10 is recessed. Next, the photoresist PR in the peripheral area 20 is removed. Furthermore, a spacer layer 400 is formed in the array area 10 and in the peripheral area 20, as shown in FIG. 2A and FIG. 2B.

In detail, as shown in FIG. 2A, the opening O1 is formed between the semiconductor structures 200 in the array area 10. However, as shown in FIG. 2B, no opening is formed between the semiconductor structures 200 in the peripheral area 20.

In some embodiments, the spacer layer 400 may include dielectric materials, such as silicon oxide. The formation of the spacer layer 400 may include a deposition process similar to that described above, such as an atomic layer deposition (ALD) process.

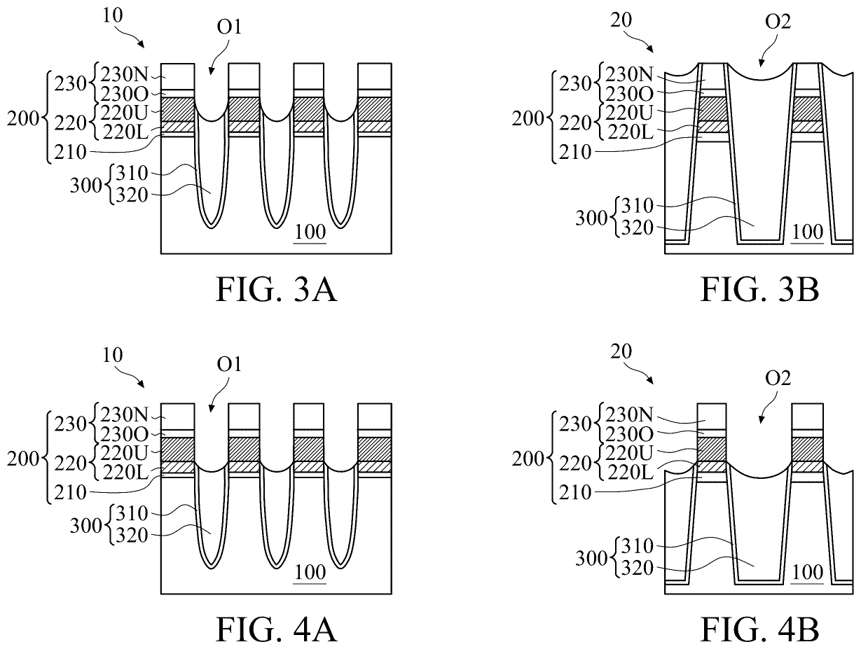

Next, referring to FIG. 3A and FIG. 3B, the isolation structure 300 in the array area 10 and in the peripheral area 20 is recessed. At this time, the spacer layer 400 is also removed.

In detail, the opening O1 and the opening O2 are respectively formed between the semiconductor structures 200 in the array area 10 and in the peripheral area 20. It should be noted that the opening O1 may become deeper due to recessing, or it may be roughly equivalent to the opening O1 in FIG. 2A. Furthermore, since the pitch between the semiconductor structures 200 in the peripheral area 20 is relatively large, the opening O2 formed in the isolation structure 300 is relatively shallow.

In some embodiments, an annealing process may be further performed on the isolation structures 300 to further strengthen the isolation structures 300.

Next, referring to FIG. 4A and FIG. 4B, the isolation structure s 300 in the array area 10 and in the peripheral area 20 are continuously recessed, so that at least a portion of the floating gate layer 220 is exposed. The top surface of the isolation structure 300 is lower than the top surface of the upper portion 220U of the floating gate layer 220 and higher than the top surface of the tunneling dielectric layer 210 (or higher than the bottom surface of the lower portion 220U of the floating gate layer 220). For example, the top surface of the isolation structure 300 intersects the top surface of the lower portion 220L of the floating gate layer 220 and completely exposes the sidewalls of the upper portion 220U of the floating gate layer 220. That is, the isolation structure 300 completely covers the sidewall of the lower portion 220L of the floating gate 220.

In other embodiments, the steps of FIGS. 2A-3A and FIGS. 2B-3B may be omitted, and the isolation structure 300 in the array area 10 and in the peripheral area 20 may be directly recessed to the desired position.

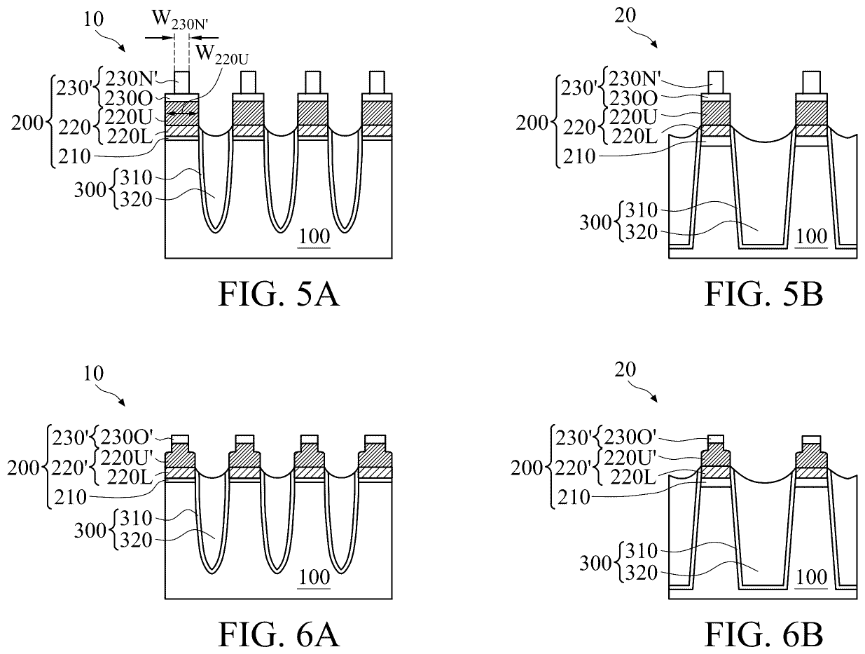

Next, referring to FIG. 5A and FIG. 5B, the protective layer 230 in the array area 10 and in the peripheral area 20 is patterned. Specifically, the nitride layer 230N in the array area 10 and the peripheral area 20 is patterned so that the opposing sidewalls of the nitride layer 230N′ are retracted from the opposing sidewalls of the floating gate layer 220.

In some examples, the upper portion 220U of the floating gate layer 220 has a width W_{220U}, and the patterned nitride layer 230N′ has a width W_{230N′}. In the embodiment of the present invention, the width W_{220U} is greater than the width W_{230N′}. In some embodiments, the ratio of width W_{230N′} to width W_{220U} may be in the range between 30% and 80%, preferably between 40% and 70%, and more preferably between 45% and 65%. Within the above range, the coverage of the subsequent control gate to the floating gate may be effectively improved and the gate coupling rate may be increased.

In some embodiments, the degree of shrinkage on the opposing sides of the nitride layer 230N′ is substantially the same. In some embodiments, the height of nitride layer 230N is also etched. That is, the nitride layer 230N is higher than the patterned nitride layer 230N′.

In some embodiments, the patterning of the nitride layer 230N may include a photolithography process and an etching process. The aforementioned etching process includes an isotropic wet etching process, such as using etching chemicals such as hot phosphoric acid (H₃PO₄). In some embodiments, using hot phosphoric acid as a wet etching process has a high etching selectivity ratio, so that the nitride layer 230N may be etched without substantially etching other film layers.

Next, referring to FIG. 6A and FIG. 6B, the patterned protective layer 230 is used as an etching mask to etch the floating gate layer 220 of each semiconductor structure 200 in the array area 10 and in the peripheral area 20. Specifically, the patterned nitride layer 230N′ is used as an etching mask to etch the underlying oxide layer 230O. Next, using the etched oxide layer 230O′ as an etching mask, the underlying floating gate layer 220 is etched. Furthermore, when the floating gate 220 is etched, the nitride layer 230N′ is also etched away.

In some embodiments, since an anisotropic etching process is used to etch the floating gate layer 220, the upper portion 220U of the floating gate layer 220 is etched, and the top surface of the etched upper portion 220U of the floating gate layer 220 is curved and has a protrusion.

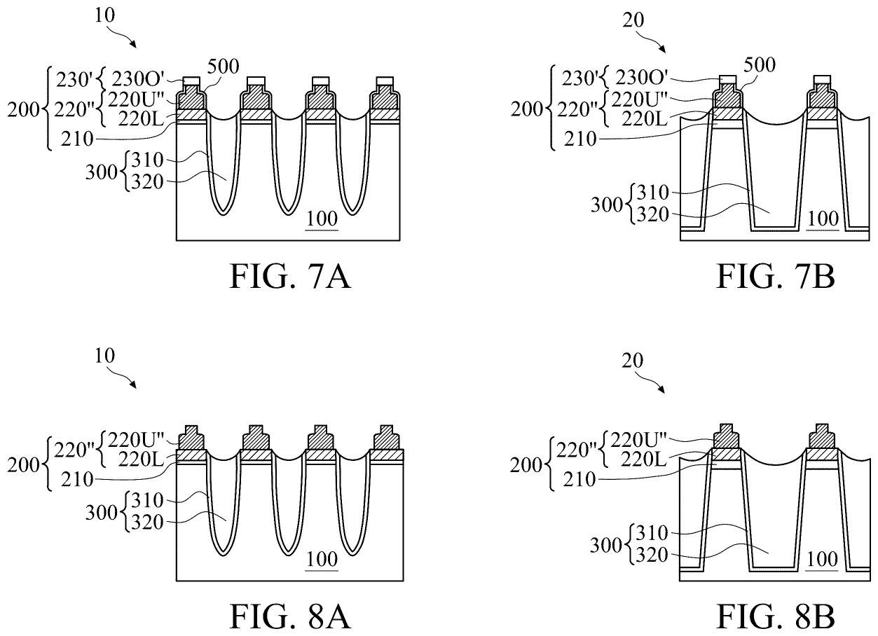

Next, referring to FIG. 7A and FIG. 7B, the floating gate layer 220′ of each semiconductor structure 200 in the array area 10 and in the peripheral area 20 is oxidized, and the remaining floating gate layer 220′ is viewed as a floating gate 220″. Furthermore, a floating gate oxide layer 500 is formed on side surfaces of the floating gate 220″ to protect the floating gate 220″. Specifically, the exposed portion of the floating gate layer 220′ (or the portion of the floating gate 220′ not covered by the isolation structure 300), such as the side surface, is oxidized.

In some embodiments, the ratio of the thickness of the floating gate oxide layer 500 and the width of the floating gate layer 220′ may be 3%-20%. Within this range, a certain amount of charge may be accumulated in the floating gate.

In some embodiments, the sum of twice of the thickness of the floating gate oxide layer 500 and the width of the upper portion 220U″ of the floating gate 220″ is substantially equal to the width of the lower portion 220L of the floating gate 220″. That is, the width of the upper portion 220U″ of the floating gate 220″ is less than the width of the lower portion 220L of the floating gate 220″.

Next, referring to FIG. 8A and FIG. 8B, the oxide layer 230O′ and the floating gate oxide layer 500 of each semiconductor structure 200 in the array area 10 and in the peripheral area 20 are removed. The removal of the oxide layer 230O′ and the floating gate oxide layer 500 may include an etching process similar to that described above, such as wet etching with etching selectivity, to remove the oxide layer 230O′ and floating gate oxide layer 500 without substantially affecting the floating gate 220′. It should be noted that both the oxide layer 230O′ and the floating gate oxide layer 500 contain oxides and therefore can be removed in the same step. As shown in FIG. 8, the top surface of one of the semiconductor structure 200 adjacent isolation structures 300 is abutted against the top surface of the lower portion 220L of the floating gate 220″. For example, the highest point of the top surface of the isolation structure 300 is at the same height as the top surface of the lower portion 220L of the floating gate 200″.

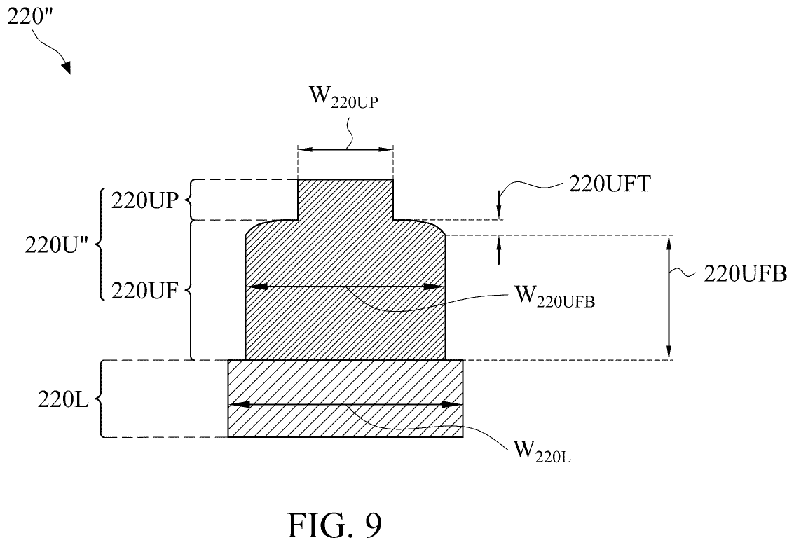

Next, refer to FIG. 9, which is an enlarged cross-sectional view of the floating gate 220″ in FIG. 8A. In FIG. 9, the upper portion 220U″ has a flat part 220UF and a protruding part 220UP protruding from the flat part 220UF. The protrusion part 220UP has a width W_{220UP}. The flat part 220UF has a body region 220UFB and a top surface region 220UFT on the body region 220UFB. The width of the top surface region 220UFT changes with the height. For example, the width of the top surface region 220UFT becomes smaller as it approaches the protrusion 220UP. The body region 220UFB has width W_{220UFB}. The lower portion 220L has width W_{220L}, which is greater than the width W_{220UFB}, which is greater than the width W_{220UP} (W_{220L}>W_{220UFB}>W_{220UP}).

In some embodiments, the ratio of the width W_{220UP} of the protruding part 220UP to the width W_{220UFB} of the body region 220UFB of the flat part 220UF may be greater than 0 and less than 1, such as between 0.3˜0.8, or further between 0.4˜0.7. In some embodiments, the ratio of the width W_{220UFB} of the body region 220UFB of the flat part 220UF to the width W_{220L} of the lower portion 220L may be greater than 0 and less than 1, such as between 0.4˜0.95, or further between 0.5˜0.85. Within the above range, it is possible to increase the coverage area of the subsequently formed control gate to the floating gate 220″ while retaining the number of electrons in the floating gate 220″.

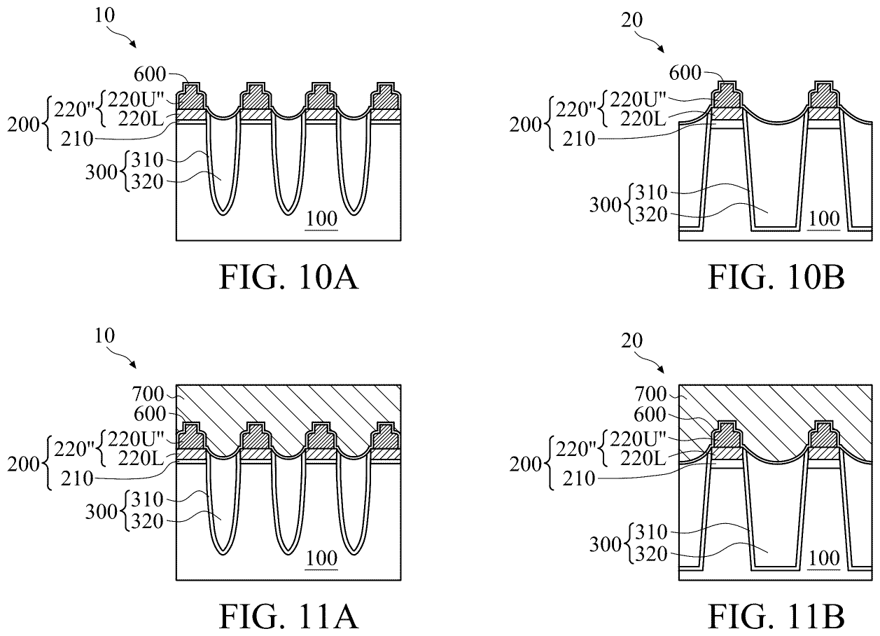

Next, referring to FIG. 10A and FIG. 10B, a dielectric structure 600 is formed on each semiconductor structure 200 in the array area 10 and in the peripheral area 20. In some embodiments, the dielectric structure 600 may include high-k dielectric materials, such as a multi-layer structure of silicon oxide layer/silicon nitride layer/silicon oxide layer (oxide-nitride-oxide, ONO) or a single layer structure of hafnium oxide (HfO).

Next, referring to FIG. 11A and FIG. 11B, a control gate 700 is formed on the dielectric structure 600 in the array area 10 and in the peripheral area 20. In some embodiments, the control gate 700 may include conductive materials such as doped or undoped polysilicon, amorphous silicon, metal, metal nitride, conductive metal oxide, or combinations thereof.

Based on the above, by the profile of the floating gate (referring to FIG. 9), the coupling rate of the control gate to the floating gate may be increased.

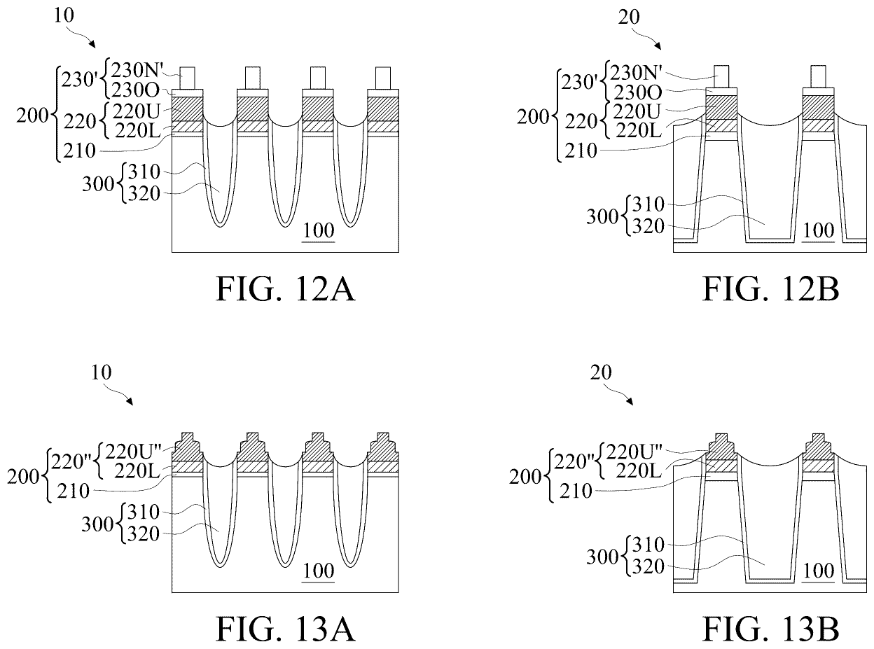

According to other embodiments of the present invention, FIGS. 12A-13A and FIG. 15A show cross-sectional views of semiconductor devices formed in the array area 10; FIGS. 12B-13B and FIG. 15B show cross-sectional views of semiconductor devices formed in the peripheral area 20.

FIG. 12A and FIG. 12B are a continuation of FIG. 3A and FIG. 3B. The isolation structure 300 in the array area 10 and the peripheral area 20 are recessed to expose a portion of the floating gate layer 220. In the embodiments of FIG. 12A and FIG. 12B, the top surface of the isolation structure 300 intersects any sidewall of the upper portion 220U of the floating gate layer 220, and only exposes a portion sidewall of the upper portion 220U of the floating gate layer 220. That is, in addition to completely covering the sidewall of the lower portion 220L of the floating gate 220, the isolation structure 300 also covers a portion of the sidewall of the upper portion 220U of the floating gate 220.

Next, the protective layer 230 in the array area 10 and in the peripheral area 20 is patterned to obtain the device as shown in FIG. 12A and FIG. 12B. That is, FIG. 12A and FIG. 12B are similar to FIG. 5A and FIG. 5B, and the difference lies in the top surface of the isolation structure 300 intersects at the sidewall between the top surface and the bottom surface of the upper portion 220U of the floating gate layer 220. Thereby, the lower portion 220L of the floating gate 220 may be further protected from being affected by subsequent processes.

Next, similar to the methods of FIGS. 6A-7A and FIGS. 6B-7B, the devices as shown in FIG. 13A and FIG. 13B are formed. That is, FIG. 13A and FIG. 13B are similar to FIG. 8A and FIG. 8B, and the difference lies in the profile of the floating gate 220″ and its relative position to the isolation structure 300. Specifically, the highest point of the top surface of one of the semiconductor structure 200 adjacent isolation structures 300 is higher than the top surface of the lower portion 220L of the floating gate 220″.

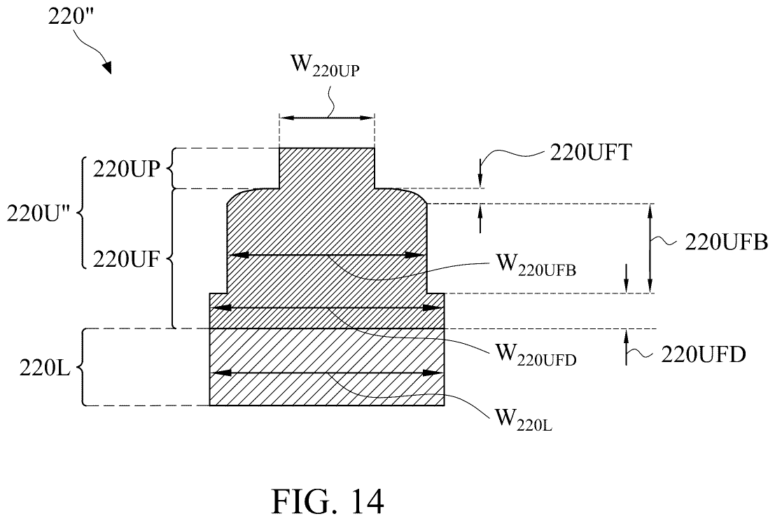

For details, referring to FIG. 14, which is an enlarged cross-sectional view of the floating gate 220″ in FIG. 13A. FIG. 14 is similar to FIG. 9, and the difference lies in the flat part 220UF of the upper portion 220U″ of the gate electrode 220″ further includes a bottom region 220UFD. The bottom region 220UFD has a width W_{220UFD} that is greater than the width W_{220UFB} of body region 220UFB. The width W_{220UFD} of this bottom region 220UFD is the same as the width W_{220L} of the lower portion 220L.

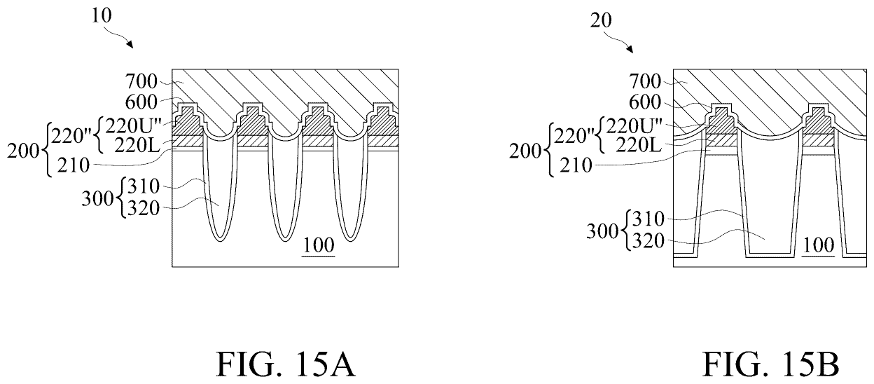

Next, similar to the method of FIG. 10A and FIG. 10B, the device as shown in FIG. 15A and FIG. 15B is formed. That is, FIG. 15A and FIG. 15B are similar to FIG. 11A and FIG. 11B, and the difference lies in the relative position of the dielectric structure 600. In detail, the dielectric structure 600 only covers a portion of the upper portion 220U″ of the floating gate 220″. Thereby, a short circuit between the floating gates 220″ of two adjacent semiconductor structures 200 is further prevented.

In summary, embodiments of the present invention may improve the gate coupling rate between the floating gate and the control gate while preventing two floating gates from being short-circuited by having the floating gate with an upper portion and a lower portion including a protruding part and a flat part. Furthermore, the protruding part provided by the present invention increases the coverage of the control gate to the floating gate. Furthermore, as the upper portion of the floating gate with dopants, the number of electrons in the floating gate is increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a plurality of isolation structures disposed in the substrate;
a plurality of semiconductor structures disposed between the isolation structures, wherein each semiconductor structure comprises:
a tunneling dielectric layer disposed on the substrate; and
a floating gate disposed on the tunneling dielectric layer,
wherein the floating gate comprises an upper portion and a lower portion,
wherein a width of the lower portion is greater than or equal to a width of the upper portion,
wherein the upper portion comprises: a flat part and a protruding part protruding from the flat part,
wherein a width of the flat part is greater than a width of the protruding part,
a dielectric structure disposed on the semiconductor structures; and
a control gate disposed on the dielectric structure.

2. The semiconductor device as claimed in claim 1, wherein the upper portion has a dopant and the lower portion does not have a dopant.

3. The semiconductor device as claimed in claim 1, wherein the flat part comprises a body region and a top surface region disposed thereon, wherein a width of the top surface region becomes smaller closer to the protruding part.

4. The semiconductor device as claimed in claim 3, wherein the flat part further comprises a bottom region disposed under the body region, wherein a width of the bottom region is greater than a width of the body region.

5. The semiconductor device as claimed in claim 4, wherein the width of the lower portion is the same as the width of the bottom region of the flat part of the upper portion.

6. The semiconductor device as claimed in claim 3, wherein the ratio of the width of the protruding part to the width of the body region of the flat part is greater than 0 and less than 1.

7. The semiconductor device as claimed in claim 1, wherein top surfaces of the isolation structures adjacent to one of the semiconductor structures is abutted against a top surface of the lower portion of the floating gate.

8. The semiconductor device as claimed in claim 1, wherein a highest point of top surfaces of the isolation structures adjacent to one of the semiconductor structures is higher than or at the same height as a top surface of the lower portion of the floating gate.

9. The semiconductor device as claimed in claim 1, wherein the substrate has an array area and a peripheral area surrounding the array area, wherein a pitch of the semiconductor structures in the peripheral area is greater than a pitch of the semiconductor structures in the array.

10. A method for forming a semiconductor device, comprising:
providing a substrate; and
forming a plurality of semiconductor structures and a plurality of isolation structures on the substrate, wherein the semiconductor structures and the isolation structures are staggered, wherein forming each of the semiconductor structures comprises:
sequentially forming a floating gate layer and a protective layer on the substrate;
recessing the isolation structures to expose a portion of the floating gate layer of each semiconductor structure;
patterning the protective layer of each semiconductor to shrink a width of the protective layer;
using the patterned protective layer as an etching mask, etching the floating gate layer of each semiconductor structure to form the floating gate layer that is narrow at top and wide at bottom; and
oxidizing the floating gate layer that is narrow at top and wide at bottom of each semiconductor structure that is not covered by the isolation structure, and the remaining floating gate layer used as a floating gate with three different widths.

11. The method as claimed in claim 10, wherein the floating gate layer of each semiconductor structure comprises: an upper portion and a lower portion,
wherein recessing the isolation structures comprises: making a top surface of the isolation structures lower than a top surface of the upper portion of the floating gate layer of each semiconductor structure and higher than a bottom surface of the lower portion of the floating gate layer of each semiconductor structure.

12. The method as claimed in claim 11, wherein recessing the isolation structures comprises: completely exposing sidewalls of the upper portion of the floating 2 gate layer of each semiconductor structure.

13. The method as claimed in claim 11, wherein recessing the isolation structures comprises: exposing a portion of sidewalls of the upper portion of the floating 5 gate layer of each semiconductor structure.

14. The method as claimed in claim 11, wherein oxidizing the floating gate layer comprises: oxidizing the floating gate layer of each semiconductor structure whose sidewalls are not covered by the isolation structures so that the upper portion is retracted from the lower portion.

15. The method as claimed in claim 10, wherein the protective layer of each semiconductor structure comprises: an oxide layer and a nitride layer on the oxide layer, wherein patterning the protective layer of each semiconductor structure comprises: retracting opposing sidewalls of the nitride layer from opposing sidewalls of the floating gate layer by using a wet etching process.

16. The method as claimed in claim 15, wherein the wet etching process uses hot phosphoric acid (H₃PO₄) as etching chemical.

17. The method as claimed in claim 15, wherein using the patterned protective layer as the etching mask, etching the floating gate layer of each semiconductor structure comprises: using the nitride layer as an etching mask, anisotropically etching the oxide layer; and
using the etched oxide layer as an etching mask, anisotropically etching the floating gate layer, wherein in the step of etching the floating gate layer, the nitride layer is also etched.

18. The method as claimed in claim 10, further comprising:
forming a floating gate oxide layer on sidewalls of the floating gate layer after oxidizing the floating gate layer; and
removing the floating gate oxide layer and the protective layer.

19. The method as claimed in claim 18, wherein a ratio of a width of the floating gate oxide layer to a width of the floating gate layer is 3%-20%.

20. The method as claimed in claim 10, further comprising:
forming a dielectric structure on the floating layer; and
forming a control gate on the dielectric structure.
